(19) United States
(12) Patent Application Publication
(10) Pub. No.: US 2022/0369480 A1
(43) Pub. Date: Nov. 17, 2022

(54) Insulated Transparent Display for an Appliance

(71) Applicant: GHSP, Inc., Grand Haven, MI (US)

(72) Inventors: IAN SAGE, Holland, MI (US); CORT C. CORWIN, Grand Haven, MI (US)

(21) Appl. No.: 17/761,452

(22) PCT Filed: Sep. 17, 2020
(86) PCT No.: PCT/US2020/051220

§ 371 Date: Mar. 17, 2022

Related U.S. Application Data
(60) Provisional application No. 62/901,447, filed on Sep. 17, 2019.

(51) Int. Cl. H05K 5/02; H05K 5/00; F24C 15/04; F24C 15/34; F24C 7/08; F24C 15/00; B32B 17/06; B32B 5/18

(52) U.S. Cl. CPC H05K 5/0209; H05K 5/0018; F24C 15/04; F24C 15/34; F24C 7/085; F24C 7/086; F24C 15/008; B32B 17/066; B32B 5/18; B32B 2266/126; B32B 2307/732; B32B 2307/412; B32B 2307/304; B32B 2509/00; B32B 2457/208; B32B 2266/057

(57) ABSTRACT

An appliance has an insulated compartment with a door that is movable between a closed position and an open position for accessing an interior cavity of the insulated compartment. A window panel is disposed at the door for viewing the interior cavity when the door in in the closed position. A display overlays at least a portion of the window panel, so as to display information that is visible at an exterior surface of the door. The display is also at least partially transparent for viewing the interior cavity through the window panel and the display. A transparent thermal insulator is disposed between the window panel and the display to prevent the interior cavity from heating or cooling the display outside of an operating temperature range.

### CROSS-REFERENCE TO RELATED APPLICATION

This application claims priority under 35 U.S.C § 119(e) to U.S. Provisional Patent Application No. 62/901,447, filed Sep. 17, 2019, the disclosure of this prior application is considered part of this application and is hereby incorporated by reference in its entirety.

### TECHNICAL FIELD

The present disclosure generally relates to a transparent display integrated with a window panel of an appliance, such as an oven door window or the like.

### BACKGROUND

In recent years, residential kitchens have become more integrated with technology, from smart devices to the internet of things (IOT), increasing connectivity with traditional appliances and providing additional functionality. Also, it is becoming more common for people to use and organize information digitally, such that easily viewable and accessible digital displays are increasingly being installed in frequently accessed rooms and environments, such as residential kitchens.

### SUMMARY

The present disclosure provides an appliance that has a thermally insulated compartment or chamber with a digital window assembly for the user to view the interior of the compartment or chamber. The digital window assembly has a display to present images and information to the user at the transparent window or panel used to view the compartment or chamber. In some implementations, the thermally insulated compartment may have a door, such as an oven door, that is movable between a closed position and an open position for accessing an interior cavity of the thermally insulated compartment. The door of the appliance may be provided with a digital window assembly that is capable of providing both optical viewing of the interior cavity and displayed content to a user. A window panel or interior glass panel may be provided on the door facing the interior cavity of the appliance. A transparent display may overlay at least a portion of the interior glass panel, such that the interior cavity can be viewed through the display and the interior glass panel on the door. A transparent thermal insulator is disposed between the interior glass panel and the display to prevent the interior cavity from heating or cooling the display outside of its general operating temperature range. Accordingly, the display may display images and information during the operation of the appliance that is visible to the user, such as information related to operational information of the appliance, cooking instructions, augmented display information associated with the contents of the appliance, general information, such as the current time and weather, or more user specific information, such as a family calendar or grocery list, or other media or advertising or the like.

According to one aspect of the present disclosure, an appliance has an insulated compartment with a door that is movable between a closed position and an open position for accessing an interior cavity of the insulated compartment. A window panel is disposed at the door for viewing the interior cavity when the door in in the closed position. A display overlays at least a portion of the window panel, so as to display information that is visible at an exterior surface of the door. The display is also at least partially transparent for viewing the interior cavity through the window panel and the display. A transparent thermal insulator is disposed between the window panel and the display to prevent the interior cavity from heating or cooling the display outside of an operating temperature range, such as approximately between 32 and 120 degrees Fahrenheit.

In some implementations, the appliance may be an oven, such as a microwave oven, a toaster oven, a convection oven, or a conventional oven. The oven, in some examples, may use a heating element to directly or indirectly heat the interior cavity for cooking food, such as to at least around 300 or 400 degrees Fahrenheit or more.

To provide optical transparency, the transparent thermal insulator may have a visible transmittance of greater than 70% and in some implementations greater than 90% or 95%. The transparent thermal insulator may include a silica aerogel material, which may have a thickness of greater than approximately 10 mm or in some implementations generally between 20 mm and 30 mm. The transparent thermal insulator may have a generally consistent thickness to provide a generally uniform insulation barrier for the display. In some implementations, the transparent thermal insulator may be fixed to the window panel, such as with an optically clear adhesive.

Optionally, the window panel may include a glass-ceramic, silica glass, a borosilicate glass, or a soda-lime glass. In some implementations, a touch screen, such as a touch-sensor circuit, may overlay at least a portion of the display to enable the display to be interactive by touch (i.e., a touchscreen). In some implementations, the display may be a light emitting diode (LED) display, such as a backlit LED display or an organic light emitting diode (OLED) display.

According to another aspect of the present disclosure, a digital window assembly is provided for an appliance door that accesses an interior cavity of an appliance. The digital window assembly may include an interior glass panel that is configured to face the interior cavity of the appliance. A display may overlay the interior glass panel, where the display is at least partially transparent for viewing the interior cavity through the display and the interior glass panel. A transparent thermal insulator is disposed between the interior glass panel and the display to prevent the interior cavity from heating or cooling the display outside of an operating temperature range.

In some implementations, the transparent thermal insulator may include a silica aerogel material, such as a wafer of silica aerogel material, which may be adhered to the interior glass panel to provide structural support to the transparent thermal insulator. Further, in some implementations, an exterior glass panel may be disposed exterior to the transparent thermal insulator. The exterior glass panel may include at least one of a glass-ceramic, a borosilicate glass, or a soda-lime glass and may also be adhered to transparent thermal insulator.

Optionally, a touch screen overlay may be disposed over an exterior surface of the display for enabling the display to be interactive by touch. In some implementations the touch screen overlay is attached at the outer surface of the display and in further implementations the touch screen overlay is attached to an exterior glass panel that is disposed over the outer surface of the display. Also, the display may include a light emitting diode (LED) display that is configured to operate with backlighting provided by a light source that illuminates the interior cavity of the appliance, such as an oven light. Further, a controller or control circuitry may be provided to control the display, such as to display information at a first portion of the display, while a second portion of the display may be void of displayed information to maintain an optical viewing path to the interior cavity of the appliance.

These and other objects, advantages, purposes, and features of the present disclosure will become apparent upon review of the following specification in conjunction with the drawings.

### BRIEF DESCRIPTION OF THE DRAWINGS

FIG. 1 is a perspective view of a wall oven in a kitchen environment, showing a display area on the door of the wall oven;

FIG. 2 is an exploded perspective view of the wall oven of FIG. 1;

FIG. 3 is a front elevation view of a door of the wall oven of FIG. 2, showing information displayed in the display area of the door;

FIG. 4 is a cross-sectional side elevation view of the wall oven, taken at line 4-4 shown in FIG. 3;

FIG. 5 is an enlarged cross-sectional view of the door shown in section A of FIG. 4;

FIG. 5A is a cross-sectional view of another oven door;

FIG. 6A is a graph of light transmission comparing transparent aerogel with glass;

FIG. 6B is a bar graph of R-values comparing transparent aerogel with glass;

FIG. 7 is a perspective view of an inductive cooktop having a top plate exploded upward to show a transparent thermal insulator in a tiled arrangement; and

FIG. 7A is an enlarged view of the transparent thermal insulator shown in FIG. 7.

### DETAILED DESCRIPTION

Referring now to the drawings and the illustrative embodiments depicted therein, a digital window assembly 10 is integrated with an appliance 12 that has a thermally insulated compartment 14 or chamber. The digital window assembly 10 provides optical viewing of an interior cavity 16 of the thermally insulated compartment 14 through the window assembly 10 and may also provide displayed content to a user at the window assembly. The digital window assembly 10 is thermally configured to operate with an appliance that has operating temperatures in the interior cavity 16 that are outside of the operating temperature range of the display component of the digital window assembly 10, such as an operating temperature range of approximately between 32 and 120 degrees Fahrenheit for the display 18 of the digital window assembly 10. Accordingly, in different implementations, the appliance incorporating a digital window assembly may be an oven, a dishwasher, a clothes washer or drier, a grill, a freezer, an ice maker, or other similar appliances. For example, the appliance may be an oven, such as a microwave oven, a toaster oven, a convection oven, or a conventional oven or the like that is used to heat or cook food.

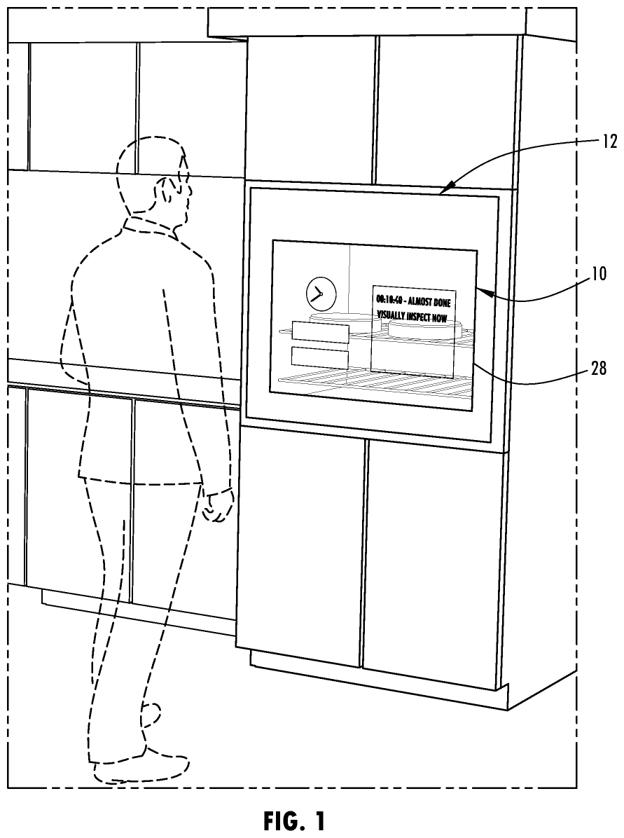

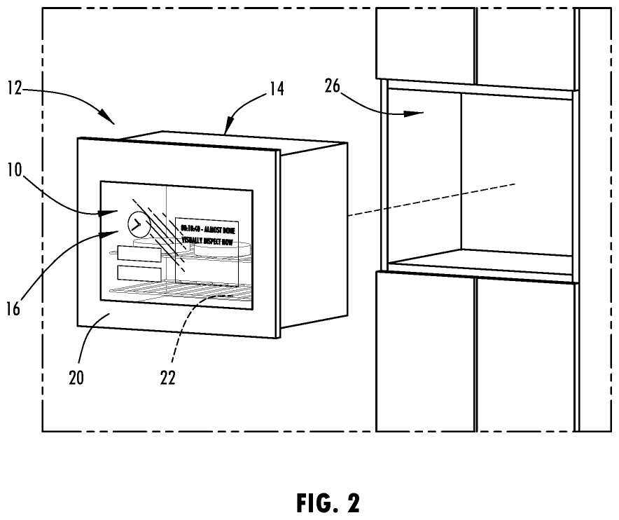

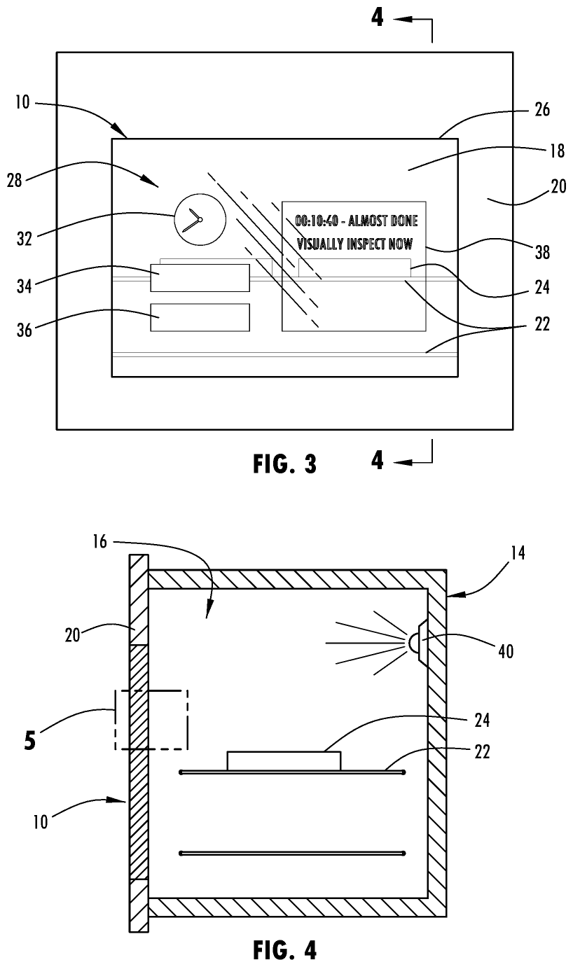

As shown in FIGS. 1-4, the appliance is a wall oven 12 that has a top wall, a bottom wall, a rear wall, and two opposing side walls that together form a thermally insulated compartment 14. In some implementations, the oven 12 may use a heating element (i.e., gas or electric) to directly or indirectly heat the interior cavity 16 to at least around 300 to 500 degrees Fahrenheit. The appliance also has a door 20 at the front of the oven 12 that moves (e.g., pivots downward about a lower hinge) between a closed position that generally encloses the interior cavity 16 of the oven 12 and an open position for accessing the interior cavity 16 of the oven 12. In other examples, a wall oven unit may include more than one compartment, such as a double oven with separated upper and lower compartments that each have a door. The interior cavity 16 of the oven may include racks or shelving, such as the rack 22 shown in FIGS. 2-4, where the rack 22 is supporting a baking dish 24 in FIGS. 3 and 4.

As shown in FIGS. 1 and 2, the wall oven 12 is installed in an elevated cabinet opening 26 with the elevated location corresponding to a general torso area of a user, such that the interior cavity 16 of the oven 12 can be easily viewed and accessed by the user, generally without the user needing to bend or crouch downward. The door 20 of the oven 12 has a central opening 26 (FIG. 3) that is fitted with the digital window assembly 10. The digital window assembly 10 has a display 18 that is at least partially transparent, such that the interior cavity 16 can be viewed through the display 18 in the central opening 26 of the door 20. In other implementations, it is contemplated that the opening on the door may be smaller or larger or in some implementations the digital window assembly may encompass substantially the entire front surface of the door. Also, other implementations may have the oven installed in a different manner or configuration, such as at a higher or lower opening or location on a cabinet or a different supportive structure.

The display 18 has a display area that operates to digitally display information to the user and others in the general environment, such as shown in FIG. 3 with the displayed content displayed at various portions on the display area 28. The displayed content may interrupt the transparency of the display 18 in the sections of the display area 28 where the displayed content is present. In other sections of the display area 28 without images or information being displayed, the display 18 remains transparent for viewing the interior cavity 16. Accordingly, the display area 28 of the digital widow assembly 10 is capable of simultaneously providing both optical viewing of the interior cavity 16 of the oven 12 and displaying content to a user at different sections of the display area 28. As shown in FIG. 3, the display 18 is disposed over the entire window assembly, such as to occupy the entire central opening 26 in the door 20. In other examples, the display may be disposed over a select section or sections of the window assembly, such as along a top, bottom, or side marginal section of window assembly.

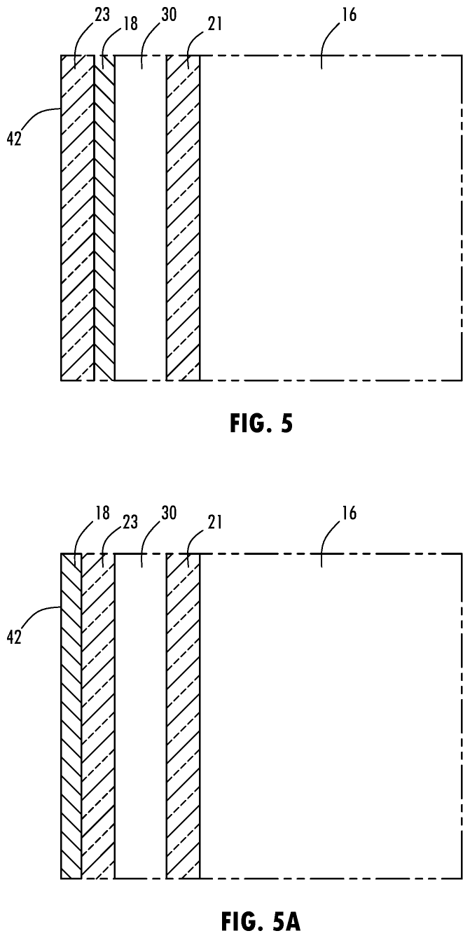

As shown in FIGS. 4 and 5, a window panel or interior glass panel 21 is disposed at the door 20, which is also generally clear and transparent to permit exterior viewing of the interior cavity 16 when the door 20 in in the closed position. The interior glass panel 21 faces the interior cavity 16 of the appliance, such that it provides the interior surface of the interior cavity 16 at the digital window assembly 10 on the oven door 20. The interior surface defined by the interior glass panel 21 may be planar, smooth, and generally configured to be easily cleaned of debris, film, or oils from cooking, such that the digital window assembly 10 maintains optical clarity. As shown in FIG. 5, the interior glass panel 21 is made of transparent glass-ceramic; however, in additional implementations the interior glass panel may include a glass-ceramic, a borosilicate glass, a soda-lime glass, or a combination thereof. The peripheral edge of the interior glass panel 21 may be attached to the door 20 about the circumference of the central opening 26 of the door 20 (FIG. 3).

To prevent the interior cavity 16 from heating or cooling the display 18 outside of its operating temperature range, a transparent thermal insulator 30 is disposed between the interior glass panel 21 and the display 18. To provide optical transparency, the transparent thermal insulator 30 may have a visible transmittance of greater than 70%, such as greater than 95%. As insulation is added between the interior cavity 16 and the display 18 to allow operation of the display 18, increases to the overall thickness of the digital window assembly beyond an acceptable thickness threshold will start to distort the optical clarity of the digital window assembly as well as result in appliance design issues, such as intrusions of the digital window assembly into the spaced designated for the interior cavity and/or issues with door construction. Accordingly, it is desirable for the thickness of the transparent thermal insulator to be less than such a thickness threshold. The transparent thermal insulator 30 must also be of a sufficient thickness (and R-value) to prevent the display 18 from heating or cooling outside of its operating temperature range. For example, when the interior cavity 16 is heated to oven temperatures, such as greater than 300, 400, or 500 degrees Fahrenheit or more, the transparent thermal insulator operates to keep the display below the display's operating temperature threshold, such as approximately 120 degrees Fahrenheit. In an alternative implementation, the transparent thermal insulator provides at least a 70 degree temperature barrier, such as for use with a freezer.

As shown in FIG. 5, the transparent thermal insulator 30 may be a transparent aerogel, such as silica aerogel, that has a thickness of greater than approximately 10 mm and generally less than 40 mm, or in some implementations generally between 20 mm and 30 mm. In additional implementations the transparent thermal insulator may also or alternatively include vacuum, argon, active fluid loop, or mechanical fan cooling.

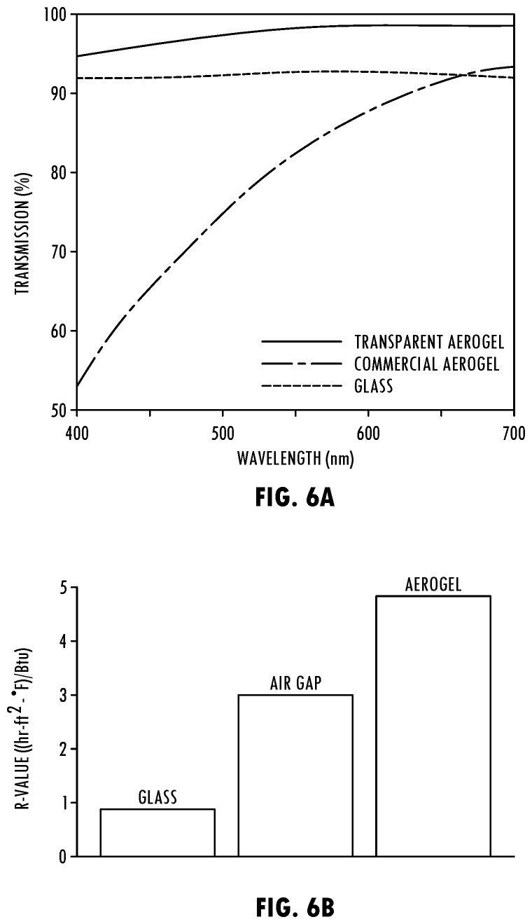

As shown in FIG. 5, the transparent thermal insulator 30 has a generally consistent thickness to provide a generally uniform insulation barrier for the display 18. The thermal conductivity of an example of transparent aerogel having a thickness of 3 mm is approximately 0.0126 W/m²K when measured on Netzsch 436 HFM. Also, the exemplary transparent aerogel has a vacuum R-value of 0.65 m²K/W when modeled at 10 kPa. When compared to air and glass, the transparent aerogel of FIG. 6B has an R-value of nearly 1.6 times that of air and nearly 5 times that of glass, where air has an R-value of approximately 3 (hr*ft2*F)/Btu), glass has an R-value of approximately 1 (hr*ft2*F)/Btu), and the transparent aerogel of FIG. 6B has an R-value of approximately 5 (hr*ft2*F)/Btu). It is contemplated that additional examples and implementations of different types of transparent aerogel may have different properties.

The transparent thermal insulator 30 has a visible transmittance generally greater than 70%, or in additional examples greater than 90% or greater than 94%. As such, the digital window assembly 10 has a visible transmittance between the front exterior surface and the interior surface, such as defined by the interior glass panel 21, is generally greater than 70%, and in additional implementations greater than 90% or greater than 94%. As shown in FIG. 6A, the visible transmittance of an example of transparent aerogel having a thickness of 3 mm is approximately 97-98% when measured on Agilent Cary 5000 UV-Vis-NIR spectrophotometer. However, it is contemplated that additional examples and implementations of different types of transparent aerogel may have different optical properties.

Further, in some implementations, the transparent thermal insulator 30 may include a transparent wafer or sheet of silica aerogel material that is substantially brittle. As such, the transparent thermal insulator 30 may be reinforced by adjacent glass panels to provide structural support to the wafer sheet of silica aerogel material. In some implementations, the transparent thermal insulator 30 may be fixed to a window panel, such as the interior glass panel 21 as shown in FIG. 5. In an additional implementation, as shown in FIG. 5A, the transparent thermal insulator 30 is also abutting an exterior glass panel 23, such that the transparent thermal insulator 30 may also or alternatively be fixed to the exterior glass panel, which may include a glass-ceramic, a borosilicate glass, a soda-lime glass, or combination thereof. In such an arrangement shown in FIG. 5A, a sandwich construction may be made with a highly thermally insulating center layer, such as the transparent thermal insulator 30 being disposed between the interior and exterior glass panels 21, 23 (FIG. 5A). The term “glass” as used in describing the glass panels refers generally to its translucent and solid properties of the material, as the glass panels may include one or more of glass-ceramic, borosilicate glass, a soda-lime glass, or combination thereof.

An optically clear adhesive (OCA) may be used to adhere the transparent thermal insulator 30 to a glass panel, both glass panels, and/or to the display panel. The OCA may be applied in a film, a laminate layer (i.e., tape), or a liquid layer that may be cured with heat, UV, or other means to provide a strong structural bond that maintains optical clarity. In addition to or in the alternative to adhesive, a flexible seal (e.g., rubber gasket or grommet) may be disposed about the perimeter of the transparent thermal insulator 30 to attach the transparent thermal insulator 30 to the door in a secure manner that is resistive to breaking upon forces of moving the door between open and closed positions.

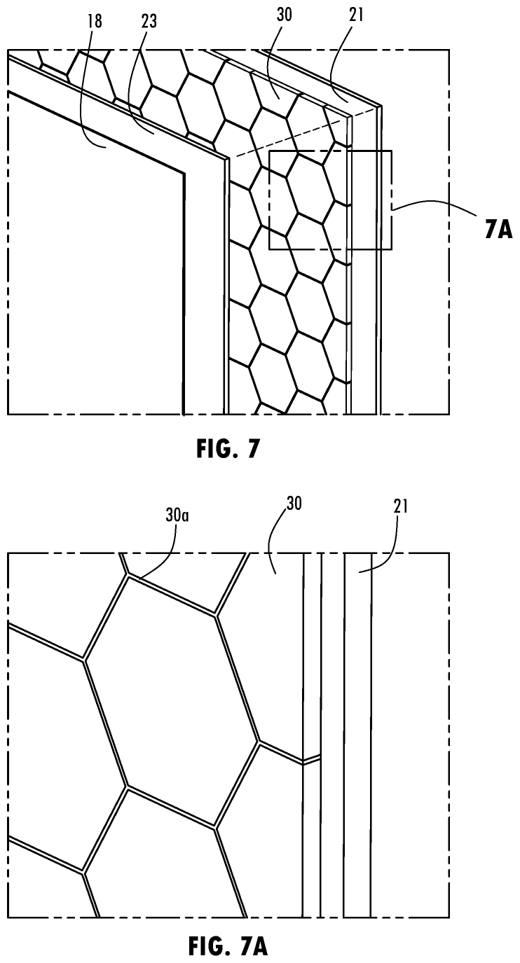

As shown in FIGS. 7 and 7A, an additional example of a transparent thermal insulator 30 is provided in a tiled arrangement. As such, the transparent thermal insulator 30 includes a number of individual tiles shaped to fit together in a planar arrangement or tessellation, such as the hexagonal shape shown in FIGS. 7 and 7A. The tiles are each formed with as a solid piece of silica aerogel, such as to have a planar outer surface that faces toward the display 18 and the exterior glass panel 23 and a planar inner surface that faces the inner glass panel 21. When arranged together, the seams between the tiles, outer surfaces of the tiles, and/or inner surface of the tiles may be filled or flooded with a refractive index matching gel or fluid 30a, as shown for example in FIG. 7A. The refractive index matching gel or fluid 30a may include an adhesive to also improve structural stability of the assembled tile panel that forms the transparent thermal insulator 30. Also, it is contemplated that a bezel or frame may be provided around a perimeter of the transparent thermal insulator 30 to contain the refractive index matching fluid 30a and secure the panel.

Referring again to FIG. 3, the appliance 12 may include a controller, such as control system circuitry, that is coupled with and in communication with the digital window assembly 10 for the controller to control the display 18. The controller or control circuitry may be provided to control the display 18, such as to display images or information at a first portion of the display area 28, while a second portion of the display area 28 may be void of displayed images or information to maintain an optical viewing path to the interior cavity 16 of the appliance. As shown in FIG. 3, the displayed content includes a clock 32 and two smaller content windows 34, 36 below the clock 32 that are displayed in a substantially opaque-manner and can be configured to display various images or information. Also, FIG. 3 shows the displayed content including a larger transparent content window 38 that provides a border around the content window 38 and information at the upper portion of the content window 38, including a timer, an indication that the timer is “ALMOST DONE,” and an alert to the user to “VISUALLY INSPECT NOW,” such that the baking dish 24 can be viewed through the content window 38 and the contents of the baking dish 24 can be inspected by the user, as instructed by the alert message. It is contemplated that various images or information may be displayed in opaque or transparent content windows or in alternative formats and arrangements, such as alternative information related to operational information of the appliance, cooking instructions, and augmented display information associated with the contents of the appliance or cookware therein.

The controller or control circuitry of the appliance 12 may control the display 18 to display images or information generated based on information from the appliance or other databases or devices. In some implementations, the displayed content may include sensed temperatures, timers, or other information stored on or sensed by the appliance. The display 18 and corresponding appliance 12 may be connected or in communication with various systems and devices, such as wireless devices, databases, internet connectivity, accessory devices, other appliances, thermostats, lighting, and security systems, among other conceivable systems and devices. Accordingly, the images displayed at the display 18 may provide a control interface for operating or otherwise allowing the user to provide operational input to the connected systems and devices and allowing feedback from connected devices to be displayed. For example, icons may be displayed for various applications that provide corresponding control interfaces, such as for a recipes, oven control, dishwasher control, home security, weather, settings (for the display or appliance), video, among various other conceivable applications.

In some implementations, the display may be implemented as a liquid crystal display (LCD), a light emitting diode (LED) display, such as an organic light emitting diode (OLED) or a quantum dot LED display (QLED). In some implementations of the display (i.e., LCD and LED), a backlight may be used to illuminate the pixels of the display. The backlighting may be provided from the edge (i.e. edge lighting) or from the back of the display. The backlighting may be provided by a light source that illuminates the interior cavity of the appliance, such as an oven light 40 as shown in FIG. 4.

As shown in FIGS. 5 and 5A, a touch screen 42, such as a touch-sensor circuit, may overlay at least a portion of the display 18 to enable the display 18 to be interactive by touch (i.e., a touchscreen). For example, the touch sensor may be disposed over the entire display area or a section of the display area. The touch sensor may include resistive, capacitive, IR, or a combination of touch technologies. The touch screen 42 overlays the display 18 and is configured for touch events at the touch screen 42 to interact with images located at corresponding locations on the display 18, such as to enable the display to be interactive by touch. In some implementations the touch screen 42 is attached to an exterior glass panel 23 that is disposed over the outer surface of the display 18, such as shown in FIG. 5, and in other implementations the touch screen 42 is attached at the outer surface of the display 18, such as shown in FIG. 5A. There are various conceivable arrangements, layouts, and settings of displayed content and user interface controls from that shown and described herein that may also be incorporated into other examples of the appliance or digital window assembly.

For purposes of this disclosure, the terms “upper,” “lower,” “right,” “left,” “rear,” “front,” “vertical,” “horizontal,” and derivatives thereof shall relate to the appliance as oriented in FIG. 1. However, it is to be understood that the appliance may assume various alternative orientations, except where expressly specified to the contrary. It is also to be understood that the specific devices and processes illustrated in the attached drawings and described in this specification are simply exemplary embodiments or implementations. Accordingly, the terminology that has been used is intended to be in the nature of words of description rather than of limitation. Hence, specific dimensions and other physical characteristics relating to the embodiments or implementations disclosed herein are not to be considered as limiting, unless the claims expressly state otherwise. Many modifications and variations of the embodiments and implementations are possible in light of the above teachings.

1. An appliance comprising:
an insulated compartment having a door that is movable between a closed position and an open position for accessing an interior cavity of the insulated compartment;
a window panel disposed at the door for viewing the interior cavity when the door in in the closed position;
a display overlaying the window panel and configured to display information that is visible at an exterior surface of the door, wherein the display is at least partially transparent for viewing the interior cavity through the window panel and the display; and
a transparent thermal insulator disposed between the window panel and the display that is configured to prevent the interior cavity from heating or cooling the display outside of an operating temperature range.

2. The appliance of claim 1, further comprising a heating element configured to heat the interior compartment to at least 400 degrees Fahrenheit.

3. The appliance of claim 1, wherein the transparent thermal insulator comprises a visible transmittance of greater than 70%.

4. The appliance of claim 1, wherein the transparent thermal insulator comprises a silica aerogel material having a thickness of less than approximately 5 mm.

5. The appliance of claim 1, wherein the transparent thermal insulator is adhered to the window panel.

6. The appliance of claim 1, further comprising a touch screen overlay for enabling the display to be interactive by touch.

7. The appliance of claim 1, wherein the display comprises a light emitting diode (LED) display.

8. The appliance of claim 8, further comprising a light source disposed at the interior cavity and operable to backlight the LED display.

9. The appliance of claim 1, wherein the display comprises an organic light emitting diode (OLED) display.

10. The appliance of claim 1, wherein the operating temperature range of the display is between 32 and 120 degrees Fahrenheit.

11. A digital window assembly for an appliance door that accesses an interior cavity of an appliance, said digital window assembly comprising:
an interior glass panel configured to face the interior cavity of the appliance;
a display overlaying the interior glass panel and configured to display information, wherein the display is at least partially transparent for viewing the interior cavity through the display and the interior glass panel; and
a transparent thermal insulator disposed between the interior glass panel and the display that is configured to prevent the interior cavity from heating or cooling the display outside of an operating temperature range.

12. The digital window assembly of claim 11, wherein the interior glass panel comprises at least one of a glass-ceramic, a borosilicate glass, or a soda-lime glass.

13. The digital window assembly of claim 11, wherein the transparent thermal insulator comprises a visible transmittance of greater than 70%.

14. The digital window assembly of claim 11, wherein the transparent thermal insulator comprises a silica aerogel material having a thickness of less than approximately 5 mm.

15. The digital window assembly of claim 11, wherein the transparent thermal insulator is adhered to the interior glass panel to provide structural support to the transparent thermal insulator.

16. The digital window assembly of claim 11, further comprising a touch screen overlay disposed over an exterior surface of the display for enabling the display to be interactive by touch.

17. The digital window assembly of claim 11, wherein the display comprises a light emitting diode (LED) display configured to operate with backlighting provided by a light source that illuminates the interior cavity of the appliance.

18. The digital window assembly of claim 11, wherein the operating temperature range of the display is between 32 and 120 degrees Fahrenheit.

19. The digital window assembly of claim 11, further comprising an exterior glass panel disposed exterior to the transparent thermal insulator, and wherein the exterior glass panel comprises at least one of a glass-ceramic, a borosilicate glass, or a soda-lime glass.

20. The digital window assembly of claim 11, wherein a controller is configured to control the display to display information at a first portion of the display, while a second portion of the display is void of displayed information to provide an optical viewing path to the interior cavity of the appliance.
